(19) United States
(12) Patent Application Publication
(10) Pub. No.: US 2010/0304526 A1
(43) Pub. Date: Dec. 2, 2010

(54) Method of making a photovoltaic module

(76) Inventors: Walter Psyk, Muenchen (DE); Joerg Reuner, Muenchen (DE); Hermann Wagner, Jena (DE)

Correspondence Address: FLYNN THIEL BOUTELL & TANIS, P.C., 2026 RAMBLING ROAD, KALAMAZOO, MI, 49008-1631, US

(21) Appl. No.: 12/800,716

(22) Filed: May 20, 2010

(30) Foreign Application Priority Data
May 22, 2009 (DE) 10 2009 022 318.5

(51) Int. Cl. H01L 31/02; H01L 31/0352

(52) U.S. Cl. 438/80; 257/E31.113; 257/E31.032; 438/98

(57) ABSTRACT

Photovoltaic module comprising a transparent substrate (1), a transparent front electrode layer (2), a semiconducting layer (3) of microcrystalline or micromorphous silicon and a rear electrode layer (4), said layers structured to form cells (C₁, C₂, C₃) electrically separated by separating lines (5, 6, 7) and electrically connected in series. A laser beam (14) is used to generate at least in rear electrode layer (4) separating line sections (18, 18′) interconnected to form continuous separating lines (7) by connecting sections (19, 20) extending at an angle (α) to separating line sections (18, 18′).

The present invention relates to a method of making a photovoltaic module as defined in the pre-characterizing portion of patent claim 1.

In the production of photovoltaic modules comprising a semiconducting layer of amorphous, microcrystalline or micromorphous silicon, it is common practice to coat glass panel substrates on their major surfaces with a transparent front electrode layer, the semiconducting layer and a rear electrode layer, which together form the photovoltaically active layers.

The monolithic layers are structured by means of a laser beam, for example, to form individual stripe-shaped cells isolated electrically by separating lines, which cells are then connected in series to obtain a module providing a desired voltage such as 12 V.

For structuring, the laser device is included in a structuring system—such as, typically, an XY coordinate table, a split-axis system or a portal or gantry system.

For example, a split-axis system comprises means to conduct a laser beam to one or more movable focussing optics disposed side by side along the X-axis to focus the laser beam in the functional layers. The coated substrate is moved through under the focussing optics in the direction of the second or Y-axis, in which the separating lines extend. In the process, the separating lines are generated in a single steady movement as continuous lines extending along the length of the photovoltaically active layer. Instead, the separating lines may be assembled sectionwise, i.e. the continuous separating line may be provided from individual sections thereof extending sequentially.

Compared with the formation of continuous separating lines in a single movement, the sequential structure of the separating lines assembled from sections significantly reduces the production costs per module.

This sequential structure of the separating lines has proved to be suited for modules having an amorphous silicon semiconducting layer. In modules using a microcrystalline or micromorphous silicon semiconducting layer, however, a sequential separating line structure of the rear electrode layer may result in malfunction, such as electric shorts of the photovoltaic module.

It is an object of the invention to provide photovoltaic modules using a microcrystalline or micromorphous silicon semiconducting layer that function perfectly while keeping production costs as low as possible.

In accordance with the invention, this object is achieved with the method characterized in claim 1. Advantageous further developments of the invention are recited in the dependent claims.

In accordance with the invention, sequentially assembled separating lines are provided at least in the rear electrode layer. The individual sections of the separating lines may be produced by means of a laser scanner with a two-axis galvanometer.

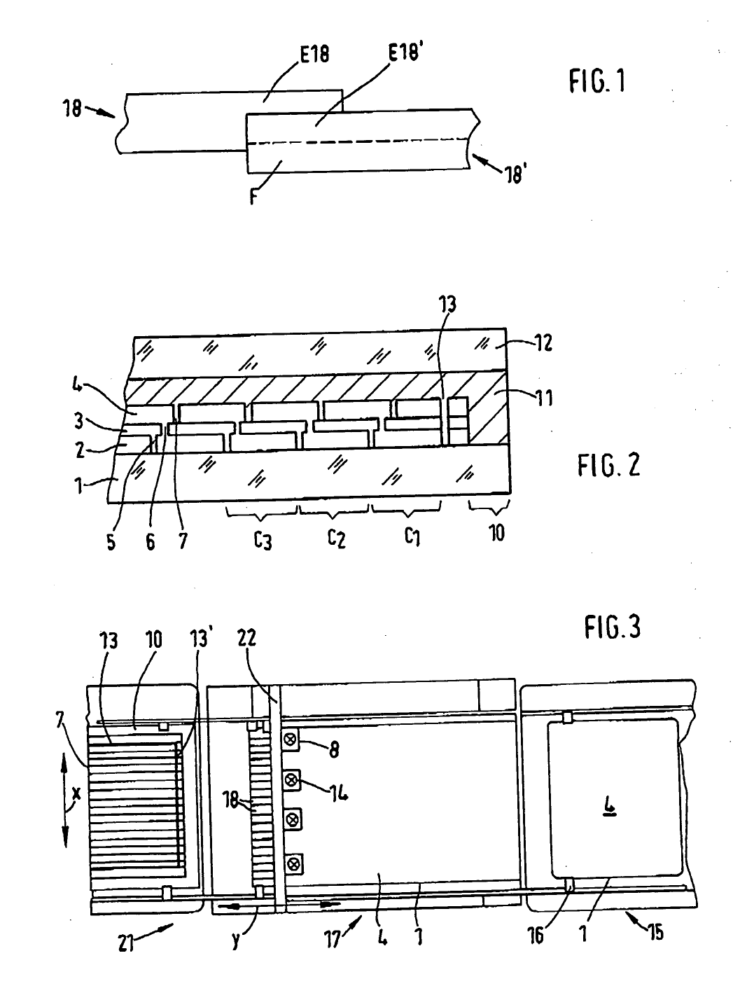

The aforesaid sequential structure of the separating lines allows the cost of generating them to be reduced. Still, and in contrast to an amorphous silicon semiconducting layer, which is relatively thin, a microcrystalline or micromorphous silicon semiconducting layer may have a thickness many times larger. As the laser beam scans the rear electrode layer, the thick microcrystalline or micromorphous silicon layer under the rear electrode layer may heat thermally to a temperature causing the rear electrode layer to snap off violently together with the semiconducting layer, thus forming the separating line sections.

Where, as shown in FIG. 1, the overlapping end portions E18 and E18′ of the first and the second separating line sections 18, 18′, respectively extend not in line but are mutually offset from each other, it is not possible, as has been found, for the rear contact layer to complete come off in area F of end portion 18′ of the second separating line section 18′. Instead, the rear contact layer material may be bent upwards and away from the transparent front electrode layer together with the semiconducting material in area F, giving rise in area F to the formation of electrically conducting strips of tinsel which may result in malfunction of the module and especially in shorts.

In order to prevent such tinsel from forming, the invention provides for the formation by means of the laser beam of connecting sections which extend at an angle to the separating lines and interconnect the sections thereof. Preferably, such connecting sections extend at a 10 to 90° angle to the separating lines, especially at a 30 to 90° angle.

The connecting section may be formed by the end portion of at least one of the two interconnected separating line sections of the rear electrode layer. Alternatively, the connecting sections may be formed by a separate section extending between the two separating line sections to be connected.

The inventive method results in a structuring of the rear electrode layer deposited on a semiconducting layer of microcrystalline or micromorphous silicon. Compared to amorphous silicon, a microcrystalline or micromorphous silicon semiconducting layer results in a higher efficiency.

Microcrystalline silicon consists of silicon crystals having particle sizes in the micrometer range. In contrast, micromorphous silicon constitutes a tandem layer of one partial layer of amorphous silicon on the side of the module which faces the light and of a second partial layer comprising microcrystalline silicon.

Preferably, the microcrystalline or micromorphous silicon semiconducting layer of the module is at least 0.6 micrometers thick; it is more preferred to be at least 1 micrometer and may be up to 2 or even 3 micrometers, for example.

The transparent front electrode layer may consist of an electrically conductive metal oxide such as tin oxide, zinc oxide or another suitable material. The rear electrode layer is preferably formed of a metal such as aluminium or silver. The substrate may be a glass panel or another electrically insulating transparent material.

The laser structuring process may be carried out with a split-axis system, a gantry system or an XY-coordinate table.

In a split-axis system, at least one layer beam is conducted to one or more laser heads having focussing optics and movable along the X direction. The laser head operates to focus the laser beam in the rear electrode layer. In the second or Y-direction, the photovoltaic module is moved through under the laser head(s). The Y-direction is the direction in which extend the separating lines structuring the rear electrode layer', in the normal case, the Y-direction is perpendicular to the X-direction.

In a gantry system the photovoltaic module is at a standstill. Instead, one or more laser heads are mounted to a portal and movable there along in the X-direction, while the portal is movable in the Y-direction. On an XY coordinate table, the module secured to the table is moved through under the one or more laser heads in the X- and Y-directions.

It is not necessary for each laser head to have a laser source of its own. Instead, the laser beam from the laser source may be split into partial beams, with each such partial beam being conducted to a laser head for focussing into the rear electrode layer by means of that head's focussing optics.

The photovoltaically active layers are encapsulated for protection from the weather and other environmental impact. To this end is used a rear surface cover such as a glass panel, which is laminated onto the active layers proper by means of an adhesive film. To allow the rear surface cover to be connected directly to the substrate by the adhesive film, the photovoltaically active layer are removed in the marginal areas of the module.

In addition to such removal of marginal areas, which may be effected by means of a laser beam also, the photovoltaically active layers are electrically insulated additionally from the module's margins by a non-conducting separating line.

Preferably, the insulating separating line in the rear electrode layer is produced sequentially by means of a laser beam also. In other words: The laser beam is used to form in the rear electrode layer insulating separating line sections which are interconnected by connecting sections so as to form continuous insulating separating lines. The connecting sections preferably extend at an angle of 10 to 90°, especially 30 to 90°, to the insulating separating line sections. The connecting section may be formed by the end portion of least one of the two insulating separating line section to be connected in the rear electrode layer or by a separate section extending between the end portions of the insulating separating line sections.

The insulating separating lines surround the photovoltaically active layer of the normally rectangular module. In other words: two isolating separating lines on opposite sides of the module extend in the Y-direction and in parallel with the structuring separating lines, while the other two isolation separating lines on the opposite side of the module extend in the X-direction.

The isolating separating lines extending in the Y-direction in the rear electrode layer may be formed—in the same manner as the structuring separating lines—of isolating separating line sections interconnected, for example, by connecting sections at the end portions thereof or by separate connecting sections.

In contrast, the separating lines extending in the Y-direction for structuring the rear electrode layer may be used for the isolating separating line sections which form the isolating separating lines extending in the X-direction in the rear electrode layer.

It is preferred for structuring the rear electrode layer to use a layer emitting in the visible range, such as a neodyme-doped solid-state laser, especially a neodyme-doped yttrium-vanadate laser (Nd:YVO₄ laser) or a neodyme-doped yttrium aluminium garnet laser (Nd:YAG laser) emitting 532 nm second harmonic light.

The structuring of the rear electrode layer is carried out preferably in pulsed laser operation—such as Q-switch operation, with the laser preferably CW-pumped and Q-switched. In the process, the laser spots may be placed one against the other in an overlapping relationship. The relative speed between the laser beam and the substrate surface should be at least 1000 mm/s, and the energy density of the laser beam should be at least 100 mJ/cm².

Laser structuring of the rear electrode layer may be effected also by means of the 355 nm third harmonic wavelength of the neodyme-doped solid-state layer, for example, or with its 1064 nm fundamental.

For example, the 1064 nm laser radiation may be directed through the transparent substrate onto the front electrode layer, which as a result will heat thermally to a temperature allowing the superimposed microcrystalline or micromorphous silicon semiconducting layer to be removed thermally together with the rear electrode layer; thereby structuring the rear electrode layer. In the structuring of the rear electrode layer, this will result in the formation of additional separating lines in the semiconducting layer; these will not affect the performance of the photovoltaic module, however.

For structuring the rear electrode layer, the laser beam may be directed onto the rear electrode layer directly. Structuring of the rear electrode layer is possible, however, by means of a laser beam from the opposite side also, i.e. through the transparent substrate.

Coating the substrate with the front electrode layer and with the microcrystalline or micromorphous silicon semiconducting layer may be effected by vapour-phase deposition, that of the semiconducting layer with the rear electrode layer by sputtering, for example.

In accordance with the invention, “separating lines” are circuitry and wiring lines as well as isolating lines.

The invention will now be explained in greater detail by embodiment examples shown in the attached drawing.

FIG. 1 is a view in plan showing the end portions of two separating lines to be connected in the rear electrode layer, said sections placed in a mutually offset relationship;

FIG. 2 is a view in section showing a portion of a photovoltaic module comprising series-connected cells;

FIG. 3 shows a front view of an assembly for providing the separating lines in the rear electrode layer;

FIG. 4 is a view in plan showing two arrays disposed side by side in the Y-direction and comprising separating line section in the rear electrode layer;

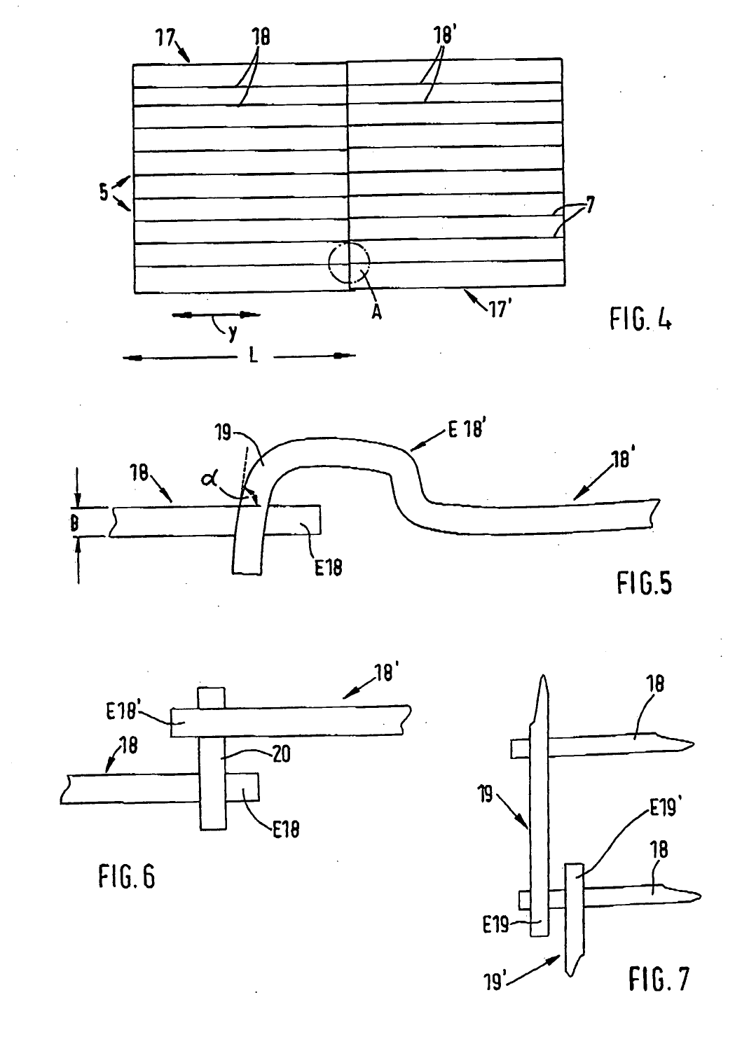

FIGS. 5 and 6 show enlarged views of area A in FIG. 4 with a connecting section between two separating line sections in accordance with a first and a second embodiment of the invention, respectively; and

FIG. 7 is a view in plan showing two isolating separating line sections interconnected by a structuring separating line.

As shown in FIG. 2, a transparent substrate 1 such as a glass panel has a transparent front electrode layer 2, a photovoltaic semiconducting layer 3 of microcrystalline or micromorphous silicon and a rear electrode layer 4, provided with separating lines 5, 6 or 7, respectively, to form series-connected stripe-shaped cells C1, C2, . . . .

In the margins 10 of module 1, layers 3, 4, 5 have been removed. Adhesive film 11 is used to laminate a rear surface cover 12 such as a glass panel onto the side of substrate 1 having layers 2, 3, 4 thereon. In this manner, substrate 2 is directly firmly connected in its margins 10 with rear cover 12 by means of said adhesive film 11, resulting in layers 2 to 4 being sealed in place. For additional isolation of layers 2, 3, 4 from margins 10, an isolating separating line 13 is provided in layers 2, 3 and in rear electrode layer 4.

Structuring separating lines 5, 6, 7 and isolating separating line 13 are produced by means of a laser beam 14.

As shown in FIG. 3, an assembly for forming separating lines 5, 6, 7, 13 comprises a charging station 15 in which the coated substrate 1 is secured in place by means of a fixture 16. From charging station 15, the coated substrate 1 is moved in the Y-direction to processing station 17 where separating lines 17 (FIG. 4) are formed in the rear electrode layer 4, among others, and to discharging station 21.

Processing station 17 comprises a plurality of laser heads 8 each with focussing optics (e.g. a galvo scan head with an f-theta objective) for focussing a laser beam 14 in rear electrode layer 4. Laser heads 8 are mounted to a holder 22 configured to form a portal and are distributed in the X-direction across the rear electrode layer 4 to be structured on substrate 1. In the process, all of laser heads 8 simultaneously provide the zone 17 thereunder with separating line sections 18 (FIG. 4) extending along the entire length L of each zone 17. The individual zones 17 join each other end to end in the X-direction. In this manner, the rear electrode layer 4 is provided across its entire width with parallel separating line sections 18 having a length L corresponding to that of zones 17. In the next step, substrate 1 is moved in the Y-direction, and this by a distance corresponding to not more than the length L of zones 17. Thereafter, each laser head 8 proceeds to form in zone 17′ a second row of parallel separating line sections 18′ extending across the entire width of substrate 1. This process is repeated until separating line sections 18, 18′ form in the rear electrode layer 4 separating lines 7 which extend in the Y-direction along the entire length of substrate 1.

Where the laser heads are equipped with fixed optics without a galvo scanner, a single separating line section per movement of the X-axis is generated in each one of zones 17. The separating line sections so generated are assembled to form a continuous separating line, and this by sequentially offsetting the laser heads in the X- or in the Y-direction.

As shown in FIG. 4, it is not possible for practical reasons to get the separating line sections 18, 18′ of neighboring zones 17, 17′ to be precisely aligned with each other. In the process of laser cutting the separating lines 7 into the rear electrode layer 4 from the material thereof, tinsel will form, which may result in malfunction of the photovoltaic module, as has been explained above under reference to FIG. 1.

For this reason, and as shown in FIGS. 5 and 6, laser heads 8 are used to cut into rear electrode layer 4 connecting sections 19, 20 which extend at an angle α to separating line sections 18, 18′ so as to interconnect the mutually offset separating line sections 18, 18′ while preventing the formation of this kind of tinsel.

As shown in FIG. 5, connecting section 19 is formed by a hook-shaped end portion E18′ on separating line section 18′, with connecting section 19 on end portion E18′ of separating line section 18′ Intersecting end portion E18 of separating line section 18 at an angle α of approximately 80°.

In accordance with FIG. 6, connecting section 20 is formed by a separate section perpendicular to end portions E18, E18′ of separating line sections 18, 18′.

The width B of separating line sections 18, 18′ and, thus, of separating lines 7 in rear electrode layer 4 may be 50 to 150 micrometers, for example. As a result, the separating line sections 18, 18′ to be interconnected may be offset from each other by more than twice or more of the width B of separating line sections 18, 18′. The separate connecting section 20 of FIG. 7 has the same width as separating line sections 18, 18′.

Laser heads 8 are used also for generating the isolating separating lines 13, 13′ surrounding the photovoltaically active layers 2, 3, 4 (FIGS. 2, 3).

The two isolating separating lines 13 extending in the Y-direction are generated sequentially using laser heads 8 and the same way as structuring separating lines 7 from structuring separating line sections 18, 18′, which may be interconnected in accordance with FIGS. 5 and 6.

The isolating separating lines 13′ extending in the X-direction are formed while substrate 1 is held stationary by moving laser heads 8 in the X-direction along holder 22 in accordance with FIG. 3.

FIG. 7 shows the end portions E19, E19′ of two isolating separating line sections 19, 19′ In rear electrode layer 4 being interconnected by one of structuring separating line sections 18.

1. A method of making a photovoltaic module comprising a transparent substrate (1) and photovoltaically active layers, the latter comprising a transparent front electrode layer (2), a silicon semiconducting layer (3) and a rear electrode layer (4), said layers being structured to form individual cells (C₁, C₂, C₃) electrically isolated from each other by separating lines (5, 6, 7) and connected in series, with the structuring at least of rear electrode layer (4) being carried out by means of a laser beam (14), characterized in that silicon semiconducting layer (3) consists of microcrystalline or micromorphous silicon and that laser beam (14) is used to generate at least in rear electrode layer (4) separating line sections (18, 18′) and connecting line sections (19, 20) extending at an angle (α) to separating line sections (18, 18′), said connecting sections connecting separating line sections (18, 18′) to form a continuous separating line (7).

2. Method as in claim 1, characterized in that connecting section (19, 20) extends at an angle (α) of 10 to 90° to separating line sections (18, 18′).

3. Method as in claim 1, characterized by connecting section (19) being formed by end portion (E18′) of at least one of the two separating line sections (18, 18′) to be connected in rear electrode layer (4).

4. Method as in claim 1, characterized by connecting section (20) being formed by a separate section extending between end portions (E18, E18′) of separating line sections (18, 18′).

5. Method as in claim 1, characterized by electrically isolating the photovoltaically active layers (2, 3, 4) from margin (10) of said module by generating an isolating separating line (13, 13′) at least in rear electrode layer (4) by means of laser beam (14), and by using laser beam (14) to generate isolating separating line sections (19, 19′) interconnected to form continuous isolating separating lines (13, 13′) by connecting sections in rear electrode layer (4) extending at an angle to isolating separating line sections (19, 19′).

6. Method as in claim 5, characterized by connecting sections which connects isolation separating line sections (19, 19′) to form a continuous isolation separating line (13) is formed by an end portion of at least one of the two interconnected separating line sections (FIG. 5) or by a separating line section (18) used for structuring rear electrode layer (4).

7. Method as in claim 1, characterized in that said microcrystalline or micromorphous silicon semiconductor layer (3) has a thickness of 0.6 to 3 micrometers.

8. Method as in claim 1, characterized by using a pulsed laser (15) for the laser structuring of rear electrode layer (4).

9. Method as in claim 1, characterized by using for the laser structuring of rear electrode layer (4) a laser (15) emitting in the visible range.

10. Method as in claim 9, characterized by using as laser (15) a frequency-doubled neodyme-doped solid-state laser emitting laser light of 532 nm wavelength.
